(19) United States
(12) Patent Application Publication
(10) Pub. No.: US 2007/0291173 A1
(43) Pub. Date: Dec. 20, 2007

(54) PHASE LOCK LOOP AND DIGITAL CONTROL OSCILLATOR THEREOF

(75) Inventor: Don Chen Hsin, Yangmei Township (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: NOVATEK MICROELECTRONICS CORP., Hsinchu (TW)

(21) Appl. No.: 11/692,930

(22) Filed: Mar. 29, 2007

(30) Foreign Application Priority Data
May 24, 2006 (TW) 95118388

(51) Int. Cl. H03L 7/00

(52) U.S. Cl. 348/538

(57) ABSTRACT

A phase lock loop including a time-to-digital converter, a period counter, a phase accumulator, a comparator, and an output unit is disclosed. The time-to-digital converter outputs a detected phase error based on the timing difference between a reference clock signal and an output clock signal. The period counter increases a first accumulative value in each period of the output clock signal. The phase accumulator increases a second accumulative value in each period of the reference clock signal and outputs the second accumulative value as an estimative phase error between the reference clock signal and the output clock signal in next period. The comparator outputs a frequency correction signal according to the detected phase error, the first accumulative value, and the estimative phase error. The output unit provides the output clock signal and adjusts its frequency according to the frequency correction signal.

### CROSS-REFERENCE TO RELATED APPLICATION

This application claims the priority benefit of Taiwan application serial no. 95118388, filed May 24, 2006. All disclosure of the Taiwan application is incorporated herein by reference.

### BACKGROUND OF THE INVENTION

1. Field of the Invention

The present invention relates to a phase lock loop. More particularly, the present invention relates to a phase lock loop for fractional-N frequency synthesis.

2. Description of Related Art

Conventional phase lock loop for fractional-N frequency synthesis is used for receiving a reference-clock signal and providing an output clock signal whose frequency is N times as high as that of the reference clock signal, wherein N dose not have to be an integer. Instead, N can be any real number greater than 0. The frequency divider of such phase lock loop is usually controlled by sigma-delta modulator to obtain the required multiple. When generating non-integer frequency multiples, sigma-delta modulator is generally used to wobble the output multiple between two adjacent integers to output non-integer multiple. For example, when a frequency 3.4 times of the reference frequency is to be output, the frequency is shifted between 3 times and 4 times of the reference frequency. With such frequency multiplication method, first, the obvious disadvantage is that the frequency error of the circuit cannot be corrected immediately; instead, it can only be corrected after certain period until the output frequency reaches a wobble mean value, which may cause delay time. Meanwhile, to filter out noises caused by the sigma-delta modulator, large loop filter has to be used. Thus, high bit number and high accuracy is difficult to be accomplished by the conventional technology, and it takes a long time to reach the desired output frequency.

### SUMMARY OF THE INVENTION

Accordingly, the present invention is directed to provide a phase lock loop for fractional-N frequency synthesis, wherein high bit number, high accuracy, and quick response to the change of N can be accomplished.

According to another aspect of the present invention, a digital control oscillator is provided to output an oscillating frequency of high bit number and high accuracy according to an inputted frequency control value.

To achieve the aforementioned and other objectives, the present invention provides a phase lock loop including a time-to-digital converter, a period counter, a phase accumulator, a comparator, and an output unit. The time-to-digital converter outputs a detected phase error based on the timing difference between a reference clock signal and an output clock signal. The period counter stores and outputs a first accumulative value, and adds 1 to the first accumulative value in each period of the output clock signal. The phase accumulator stores a second accumulative value, and the phase accumulator adds N to the second accumulative value in each period of the reference clock signal and outputs the second accumulative value as an estimative phase error between the reference clock signal and the output clock signal in next period, wherein N is a real number greater than 0. The comparator outputs a frequency correction signal according to the detected phase error, the first accumulative value, and the estimative phase error. The output unit provides the output clock signal and adjusts the frequency of the output clock signal according to the frequency correction signal so as to obtain the desired output frequency.

According to the phase lock loop in an embodiment of the present invention, the time-to-digital converter includes a plurality of buffers, a sampler, and an encoder. A first buffer receives the reference clock signal, each of the other buffers receives the output of the previous buffer, and the reference clock signal is delayed a particular time when it's passed through each buffer. The sampler captures the output of each of the foregoing buffers based on the output clock signal. Then the encoder generates a detected phase error according to the captured result of the sampler, and the estimative phase error may be the fractional part of the second accumulative value.

Moreover, the output unit may include a loop filter and a voltage control oscillator. The loop filter adjusts and outputs a frequency control value, which is an analog voltage, based on the frequency correction signal. Next, the voltage control oscillator generates the output clock signal according to the frequency control value.

The output unit may further include a bi-directional counter and a digital control oscillator. The bi-directional counter adjusts and outputs the frequency control value, which is a digital signal, according to the frequency correction signal. Besides, the digital control oscillator generates the output clock signal according to the frequency control value. After that, the bi-directional counter increases the frequency control value when the frequency correction signal is in a first state, and decreases the frequency control value when the frequency correction signal is in a second state. Meanwhile, the digital control oscillator includes an inverter and a delay module. The inverter receives the output clock signal and outputs the inverted and delayed output clock signal to the output terminal of the digital control oscillator. The delay module receives the output clock signal from the inverter and outputs the output clock signal to the inverter after delaying it for a certain time period, wherein the delay time period is determined according to the frequency control value. After that, the delay module includes a plurality of buffers and a selector. A first buffer among the buffers receives the output clock signal from the inverter, and each of the other buffers receives the output of the previous buffer. Besides, the selector provides the output of one of the foregoing buffers to the inverter according to the frequency control value.

According to the phase lock loop in an embodiment of the present invention, the digital control oscillator further includes a dithering unit. The dithering unit provides a frequency dithering value according to the frequency control value and a predetermined rule to the selector, and the output of the buffers is selected based on the frequency dithering value. Wherein the effective bit number of the frequency dithering value is smaller than the effective bit number of the frequency control value, and the average value of the frequency dithering value within a predetermined time is equal to the frequency control value. Next, the dithering unit includes a dithering accumulator for storing a third accumulative value and adding the frequency control value to the third accumulative value in each period of a clock signal. The frequency dithering value is one of A and B, A is greater than B, and the dithering unit outputs A as the frequency dithering value if the additive operation of the third accumulative value produces carry, otherwise the dithering unit outputs B as the frequency dithering value. Besides, A may be equal to B plus 1.

According to another aspect of the present invention, a digital control oscillator is provided, which includes a dithering unit, an inverter, and a delay module. The foregoing dithering unit, inverter, and delay module are all components of the phase lock loop described above; therefore they will not be further discussed.

According to the present invention, the output clock signal is feedback to a time-to-digital converter and a period counter to be corrected, thus, the phase lock loop can correct the frequency of the output clock signal repeatedly according to the difference between the detected phase error and the estimative phase error, and eventually can make the frequency of the output clock signal to be N times of the input clock frequency. Moreover, since the phase lock loop of the present invention has the function of immediately detecting and correcting the frequency of the output clock signal, the phase lock loop can quickly respond to the change of N.

The phase lock loop in the present invention can be all-digital, or the bi-directional counter and the digital control oscillator of the output unit can be replaced with a loop filter and a voltage control oscillator, so that the phase lock loop becomes a digital/analog combination. The all-digital phase lock loop for fractional-N frequency synthesis is not easily affected by process variation and has smaller surface area, while the phase lock loop with analog output unit can provide a broad and continuous frequency distribution, and features better low-jitter characteristics.

Moreover, the digital control oscillator provided by the present invention adopts a structure including a dithering accumulator and a delay module, thus, the effective bit number of the frequency control value is increased by the dithering accumulator before the frequency control value is provided to the delay module with high bit number. Accordingly, the present invention provides clock frequency multiplication with high accuracy and high bit number.

In order to make the aforementioned and other objects, features and advantages of the present invention comprehensible, a preferred embodiment accompanied with figures is described in detail below.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a circuit block diagram of a phase lock loop for fractional-N frequency synthesis according to an embodiment of the present invention.

FIG. 1B is a diagram illustrating the reference clock signal and the output clock signal of the phase lock loop for fractional-N frequency synthesis in FIG. 1A.

FIG. 2 is a circuit block diagram of a phase lock loop for fractional-N frequency synthesis according to another embodiment of the present invention.

FIG. 3 is a circuit diagram of the time-to-digital converter 101 in FIG. 1A.

FIG. 4 is a circuit diagram of an embodiment of the digital control oscillator 106 in FIG. 1A.

FIG. 5 is a circuit diagram of another embodiment of the digital control oscillator 106 in FIG. 1A.

### DESCRIPTION OF EMBODIMENTS

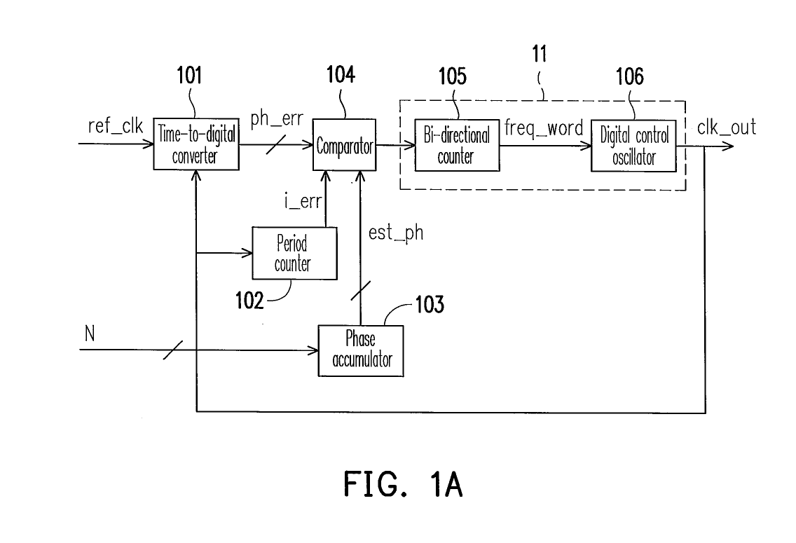

FIG. 1A is a circuit block diagram of a phase lock loop for fractional-N frequency synthesis according to an embodiment of the present invention. The phase lock loop includes a time-to-digital converter 101, a period counter 102, a phase accumulator 103, a comparator 104, and an output unit 11. Wherein the time-to-digital converter 101 outputs a detected phase error ph_err according to the timing difference between the reference clock signal ref_clk and the output clock signal clk_out. The period counter 102 stores and outputs a first accumulative value i_err and adds 1 to the first accumulative value i_err in each period of the output clock signal clk_out. The phase accumulator 103 adds N to a second accumulative value in each period of the reference clock signal ref_clk and outputs the estimative phase error est_ph according to the second accumulative value, wherein N is a real number greater than 0. In the present embodiment, the estimative phase error est_ph is the fractional part of the second accumulative value. The comparator 104 compares the integral parts of the first accumulative value i_err and N with the detected phase error ph_err and the estimative phase error est_ph to produce a frequency correction signal. The output unit 11 provides the output clock signal clk_out and adjusts the frequency of the output clock signal clk_out according to the frequency correction signal, which may be forward correction signal or backward correction signal. The output unit 11 includes a bi-directional counter 105 and a digital control oscillator 106. The bi-directional counter 105 outputs a frequency control value freq_word and forwardly or backwardly corrects the frequency control value freq_word according to the frequency correction signal. In the present embodiment, the frequency control value freq_word is a digital signal. The digital control oscillator 106 produces the output clock signal clk_out according to the frequency control value freq_word.

FIG. 1B is a diagram illustrating the reference clock signal and the output clock signal of the phase lock loop for fractional-N frequency synthesis in FIG. 1A. The operation pattern of the phase lock loop can be understood by referring to FIG. 1A and FIG. 1B. The function of the phase lock loop is to increase the frequency of the output clock signal clk_out to N times of the frequency of the reference clock signal ref_clk, in the present embodiment N is 3.872. Initially, at time TO, the predetermined phase difference between the reference clock signal ref_clk and the output clock signal clk_out is 0, and if the detected actual phase difference is not 0, the rate of the output clock signal clk_out has to be adjusted according to the detected result. Then at time T1, it is started to detect whether the frequency of the output clock signal clk_out is 3.872 times of the frequency of the reference clock signal ref_clk. Such a detection operation can be divided into two parts. The first part is to detect the integral part by using the period counter 102, and the second part is to detect fractional part by converting the timing difference into a digital value by using the time-to-digital converter 101. The current multiple of the output clock signal clk_out to the reference clock signal ref_clk can be detected from the first accumulative value i_err sent by the period counter 102 and the detected phase error ph_err sent by the time-to-digital converter 101. Besides, the phase accumulator 103 provides the estimative phase error est_ph to be compared. At time T1, through the comparison of the comparator 104, the comparator 104 sends the backward correction signal of the frequency correction signal to the bi-directional counter 105 if the frequency of the output clock signal clk_out is more than 3.872 times of the frequency of the reference clock signal ref_clk, and the bi-directional counter 105 decreases the frequency control value freq_word after receiving the backward correction signal of the frequency correction signal, accordingly the digital control oscillator 106 produces a output clock signal clk_out of slightly lower frequency. The subsequent corrections in this predetermined status at time T2, T3, and T4 can be deduced accordingly.

Thus, to accomplish the correction function, the output clock signal clk_out has to feedback to the time-to-digital converter 101 and the period counter 102, so that the entire circuit forms a closed loop correction system. In another situation, if the frequency of the output clock signal clk_out is lower than N times of the frequency of the reference clock signal ref_clk, the comparator 104 sends the forward correction signal of the frequency correction signal to the bi-directional counter 105, and the bi-directional counter 105 increases the frequency control value freq_word after receiving the forward correction signal of the frequency correction signal, accordingly the digital control oscillator 106 produces an output clock signal clk_out having higher frequency. Thus, a closed loop system is adopted in the phase lock loop in FIG. 1A so that the circuit can keep correcting the difference between the estimative phase error est_ph and the detected phase error ph_err, the first accumulative value i_err, so as to eventually make the frequency of the output clock signal clk_out to be the desired multiple of the frequency of the reference clock signal ref_clk. Because an all-digital structure is adopted in the present embodiment, the performance of the circuit will not be affected by the manufacturing process, and the area thereof can be smaller than that of the conventional analog structure.

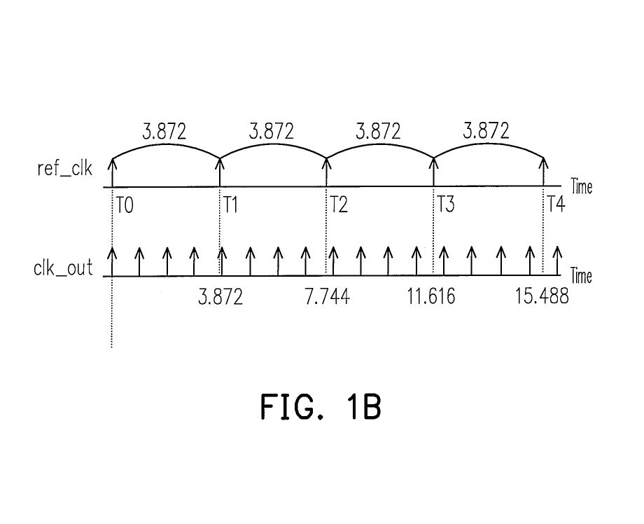

FIG. 2 is a circuit block diagram of a phase lock loop for fractional-N frequency synthesis according to another embodiment of the present invention. The major difference between this circuit block diagram and FIG. 1A is that the output unit 21 has an analog structure and is composed of a loop filter 207 and a voltage control oscillator 208. The loop filter 207 adjusts and outputs the frequency control value according to the frequency correction signal, wherein the frequency control value is an analog voltage, and meanwhile the frequency control value is output to the voltage control oscillator to produce the output clock signal clk_out. Then the output clock signal clk_out is feedback to the time-to-digital converter 201 and is compared with the reference clock signal ref_clk to produce the detected phase error ph_err. After that the period counter 202 adds 1 to the first accumulative value i_err in each period. Meanwhile, the phase accumulator 203 accumulates the multiple, for example, N times, to produce the estimative phase error est_ph. Next, the comparator 204 compares the estimative phase error est_ph and the first accumulative value i_err with the detected phase error ph_err to output the frequency correction signal to the output unit 21 for producing the output clock signal clk_out. With such an analog structure, the output clock signal clk_out can be adjusted within a large range of continuous frequency and low-jitter characteristic can be achieved.

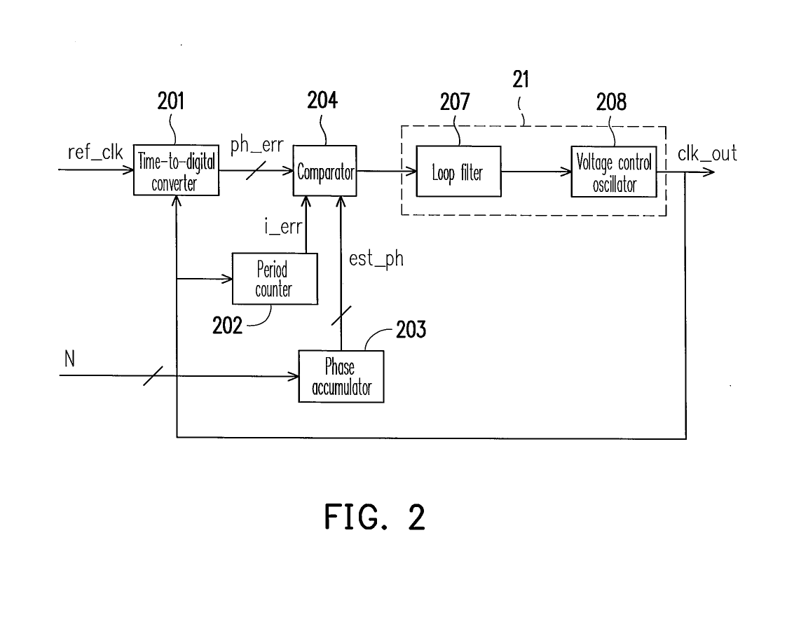

FIG. 3 is a circuit diagram of the time-to-digital converter 101 in FIG. 1A. When the reference clock signal ref_clk is passed through the buffers 301˜30n, each buffer delays the signal so that the signals at the output terminals of the buffers connected in series are delayed different time. The sampler 31 captures the signals at the output terminals of the buffers 301˜30n based on the timing of the output clock signal clk_out, and then the encoder 32 converts the thermal codes into binary codes to output the detected phase error ph_err. Accordingly, the output of the circuit can present the phase difference value between the reference clock signal ref_clk and the output clock signal clk_out, namely, the detected phase error ph_err.

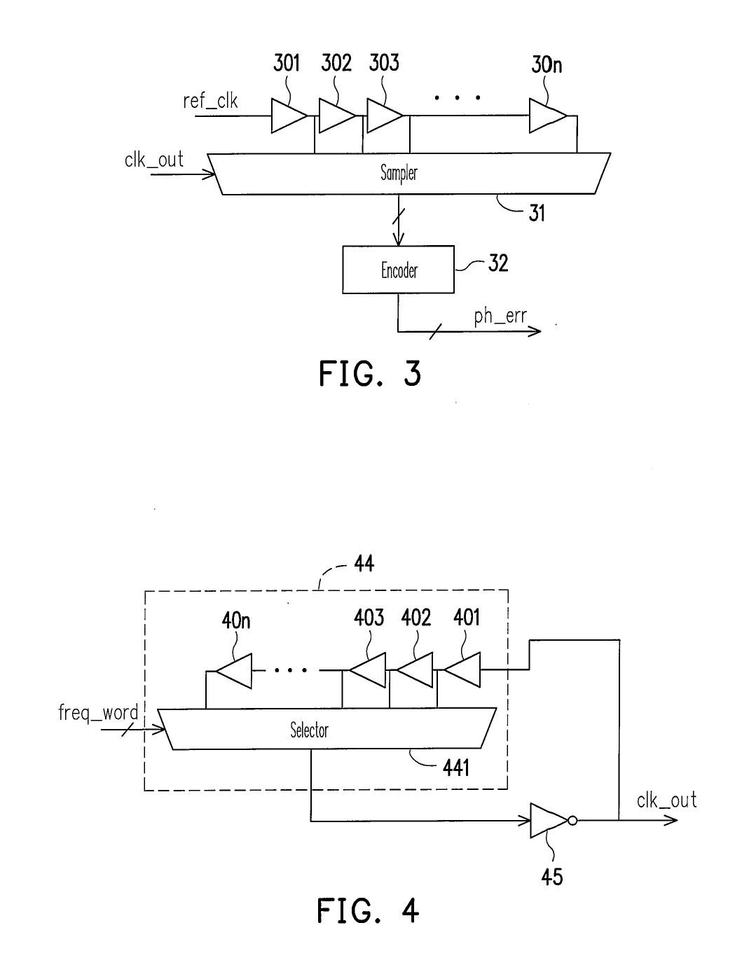

FIG. 4 is a circuit diagram of an embodiment of the digital control oscillator 106 in FIG. 1A. Wherein the delay module 44 receives the output clock signal clk_out from the output terminal of the inverter 45, and then sends the output clock signal clk_out to the input terminal of the inverter 45 after delaying the output clock signal clk_out for a certain time. The delay time of the delay module 44 determines the frequency of the output clock signal clk_out, and the foregoing delay time is determined according to the frequency control value freq_word (described in detail below). Meanwhile, the inverter 45 receives the output clock signal clk_out from the delay module 44 and output the inverted and delayed output clock signal clk_out to the input terminal of the delay module 44 and the output terminal of the digital control oscillator 106 in FIG. 1A.

The delay module 44 includes a plurality of buffers 401˜40n and a selector 441, wherein buffer 401 receives the output clock signal clk_out from the inverter 45, buffer 402 receives the signal delayed by buffer 401, then buffer 403 receives the signal delayed by buffer 402 and buffer 401, and so on, until buffer 40n. The selector 441 provides the output of one of the buffers 401˜40n to the inverter 45 according to the frequency control value freq_word, so that different delay effect can be achieved through selecting the output of different buffer, so as to control the frequency of the output clock signal clk_out.

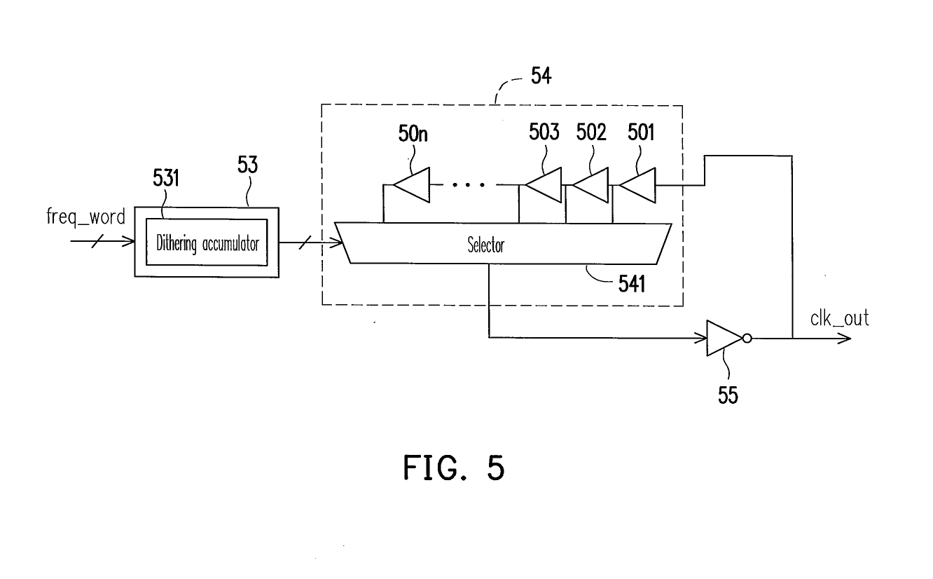

FIG. 5 is a circuit diagram of another embodiment of the digital control oscillator 106 in FIG. 1A. The difference of FIG. 5 from FIG. 4 is that the frequency control value freq_word is passed through the dithering unit 53 first, and then the dithering unit 53 outputs a frequency dithering value to the selector 541. According to this design, the frequency control value freq_word of high bit number is dithered to produce a frequency dithering value of lower bit number through the dithering algorithum of dithering unit 53, and the frequency dithering value is input to the selector. Even though the effective bit number of the frequency dithering value is low and the accuracy thereof is less than that of the frequency control value, the average value of the frequency dithering value within a certain period is equal to the frequency control value, so that the control range of the frequency control value freq_word can be improved accordingly without changing the number of buffers.

The dithering unit 53 outputs the frequency dithering value, which can be one of A and B, and A>B. The dithering unit 53 has a dithering accumulator 531 for storing a third accumulative value, and the frequency control value is added to the third accumulative value in each period of a clock signal so that the third accumulative value increases along time. In each period of the clock signal, the dithering unit outputs A as the frequency dithering value if the additive operation of the third accumulative value produces carry, and the dithering unit outputs B as the frequency dithering value if the additive operation of the third accumulative value does not produce carry. Here A may be B plus 1, and values between A and B and be presented by dithering between A and B, so as to increase the bit number to be controlled.

The frequency dithering value produced by the dithering unit 53 is input to the delay module 54. The delay module 54 receives the output clock signal clk_out from the output terminal of the inverter 55, and outputs the output clock signal clk_out to the input terminal of the inverter 55 after delaying it for certain time. The inverter 55 receives the signal output by the delay module 54, and outputs the inverted and delayed output clock signal clk_out to the output terminal of the digital control oscillator 106 in FIG. 1A. Wherein the delay module 54 includes a selector 541 and buffers 501˜50n. Buffer 501 receives the output clock signal clk_out from the inverter 55, then buffer 502 receives the signal delayed by buffer 501, and buffer 503 receives the signal delayed by buffer 502 and buffer 501, and so on, until buffer 50n. The selector 541 provides the output of one of the buffer 501˜50n to the inverter 55 according to the frequency dithering value to produce the output clock signal clk_out.

Here, the circuit of the digital control oscillator in FIG. 5 is not limited to be applied to the phase lock loop; instead, it can be applied independently to any circuit for outputting a corresponding frequency according to a digital control signal, and the circuit and operation of the digital control oscillator have been described in detail in foregoing embodiments, therefore will not be described herein.

The phase lock loop in the present invention can quickly respond to the change of the frequency multiple value N, thus, following applications can be derived. When the value of N is a function n(t) of time, first, accurate and stable spread-spectrum control can be achieved if n(t) is a period carrier wave (for example, triangle wave or sine wave). Next, the phase lock loop can be applied to direct frequency-shift keying (FSK) modulation if n(t) is the combination of two values changing along time. After that, the phase lock loop can be applied to direct frequency modulation (FM) modulation if n(t) is f(c)+f(t), wherein f(c) is carrier wave frequency, and f(t) is a modulation signal.

In summary, according to the present invention, the output clock signal is feedback to the time-to-digital converter and the period counter to be corrected, thus, the phase lock loop can repeatedly correct the frequency of the output clock signal according to the difference between the detected phase error and the estimative phase error, and eventually can make the frequency of the output clock signal to be N times of the input clock frequency. Besides, the phase lock loop in the present invention has the function of immediately detecting and correcting the frequency of the output clock signal, thus, it can quickly respond to the change of N.

The phase lock loop provided by the present invention can be all-digital, or the bi-directional counter and the digital control oscillator of the output unit can be replaced with a loop filter and a voltage control oscillator. The all-digital phase lock loop for fractional-N frequency synthesis is not easily affected by process variation and has small surface area. While the phase lock loop with analog output unit can provide a broad and continuous frequency distribution and has better low-jitter characteristics.

Moreover, the digital control oscillator provided by the present invention includes a dithering accumulator and a delay module The effective bit number of the frequency control value is increased by the dithering accumulator and then the frequency control value is provided to the delay module of high bit number, so as to provide clock multiplication frequency of high accuracy and high bit number.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A phase lock loop, comprising:
a time-to-digital converter, outputting a detected phase error according to the timing difference between a reference clock signal and an output clock signal;
a period counter, storing and outputting a first accumulative value, adding 1 to the first accumulative value in each period of the output clock signal;
a phase accumulator, storing a second accumulative value, adding N to the second accumulative value in each period of the reference clock signal, outputting an estimative phase error according to the second accumulative value, wherein N is a real number greater than 0;
a comparator, outputting a frequency correction signal according to the detected phase error, the first accumulative value, and the estimative phase error; and
an output unit, providing the output clock signal, adjusting the frequency of the output clock signal according to the frequency correction signal.

2. The phase lock loop as claimed in claim 1, wherein the time-to-digital converter comprises:
a plurality of buffers, wherein the first buffer receives the reference clock signal, and each of the other buffers receives the output of the previous buffer;
a sampler, capturing the output of the buffers based on the output clock signal; and
an encoder, producing the detected phase error according to the sampling result of the sampler.

3. The phase lock loop as claimed in claim 1, wherein the estimative phase error is the fractional part of the second accumulative value.

4. The phase lock loop as claimed in claim 1, wherein the output unit comprises:
a loop filter, adjusting and outputting a frequency control value according to the frequency correction signal, the frequency control value being an analog voltage; and
a voltage control oscillator, generating the output clock signal according to the frequency control value.

5. The phase lock loop as claimed in claim 1, wherein the output unit comprises:
a bi-directional counter, adjusting and outputting a frequency control value according to the frequency correction signal, the frequency control value being a digital signal; and
a digital control oscillator, generating the output clock signal according to the frequency control value.

6. The phase lock loop as claimed in claim 5, wherein the bi-directional counter increases the frequency control value when the frequency correction signal is in a first state, and decreases the frequency control value when the frequency correction signal is in a second state.

7. The phase lock loop as claimed in claim 5, wherein the digital control oscillator comprises:
an inverter, receiving the output clock signal, outputting the inverted and delayed output clock signal to the output terminal of the digital control oscillator; and
a delay module, receiving the output clock signal from the inverter, delaying the output clock signal a period of time and then outputting the delayed output clock signal to the inverter, the delay time period being determined according to the frequency control value.

8. The phase lock loop as claimed in claim 7, wherein the delay module comprises:
a plurality of buffers, wherein the first buffer receives the output clock signal from the inverter, and each of the other buffers receives the output of the previous buffer; and
a selector, providing the output of one of the buffers to the inverter according to the frequency control value.

9. The phase lock loop as claimed in claim 7, wherein the digital control oscillator further comprises:
a dithering unit, providing a frequency dithering value to the selector according to the frequency control value and a predetermined rule to select the output of the buffers based on the frequency dithering value, wherein the effective bit number of the frequency dithering value is smaller than the effective bit number of the frequency control value, and the average value of the frequency dithering value within a predetermined period is equal to the frequency control value.

10. The phase lock loop as claimed in claim 9, wherein the dithering unit comprises:
a dithering accumulator, storing a third accumulative value, adding the frequency control value to the third accumulative value in each period of a clock signal; and
the frequency dithering value being one of A and B, A>B, the dithering unit outputting A as the frequency dithering value if the additive operation of the third accumulative value produces carry, otherwise the dithering unit outputting B as the frequency dithering value.

11. The phase lock loop as claimed in claim 10, wherein A is equal to B+1.

12. A digital control oscillator, comprising:
a dithering unit, providing a frequency dithering value according to a frequency control value and a predetermined rule, wherein the effective bit number of the frequency dithering value is smaller than the effective bit number of the frequency control value, and the average value of the frequency dithering value during a predetermined period is equal to the frequency control value;
an inverter, receiving an output clock signal, outputting the inverted and delayed output clock signal to the output terminal of the digital control oscillator; and
a delay module, receiving the output clock signal from the inverter, delaying the output clock signal a period of time and then outputting the delayed output clock signal to the inverter, the delaying time period being determined according to the frequency dithering value.

13. The digital control oscillator as claimed in claim 12, wherein the dithering unit comprises:
a dithering accumulator, storing an accumulative value, adding the frequency control value to the accumulative value in each period of a clock signal; and
the frequency dithering value being one of A and B, A>B, the dithering unit outputting A as the frequency dithering value if the additive operation of the accumulative value produces carry, otherwise the dithering unit outputting B as the frequency dithering value.

14. The digital control oscillator as claimed in claim 13, wherein A is equal to B+1.

15. The digital control oscillator as claimed in claim 12, wherein the delay module comprises:
a plurality of buffers, wherein the first buffer receives the output clock signal from the inverter, and each of the other buffers receives the output of the previous buffer; and
a selector, providing the output of one of the buffers to the inverter according to the frequency dithering value.
